(19) United States
(12) Patent Application Publication
(10) Pub. No.: US 2025/0035703 A1
(43) Pub. Date: Jan. 30, 2025

(54) SCAN-SHIFT BUFFER ISOLATOR FOR DYNAMIC POWER REDUCTION

(71) Applicant: STMICROELECTRONICS INTERNATIONAL N.V., Geneva (CH)

(72) Inventors: Ankur BAL, Greater Noida (IN); Aradhana KUMARI, Greater Noida (IN)

(21) Appl. No.: 18/770,967

(22) Filed: Jul. 12, 2024

Related U.S. Application Data
(60) Provisional application No. 63/529,013, filed on Jul. 26, 2023.

(51) Int. Cl. G01R 31/3185

(52) U.S. Cl. CPC G01R 31/318541; G01R 31/318536; G01R 31/31858

(57) ABSTRACT

An integrated circuit is provided. For example, an integrated circuit comprises a functional data path and a scan-data path. At least a portion of the scan-data path is separate from the functional data path. The portion of the scan-data path which is separate from the functional data path comprises a combined gating/delay element for preventing a scan-data signal from reaching any elements downstream of the combined gating/delay element during a scan mode and for providing some or all of a desired signal delay in the portion of the scan-data path which is separate from the functional data path.

### CROSS-REFERENCE TO RELATED APPLICATIONS

This application claims priority to and the benefit of U.S. Provisional Patent Application Ser. No. 63/529,013, filed on Jul. 26, 2023, and titled “SCAN-SHIFT BUFFER ISOLATOR FOR DYNAMIC POWER REDUCTION,” the contents of which is incorporated herein by reference in its entirety.

### FIELD OF THE INVENTION

Example embodiments of the present disclosure relate generally to scan-test shift delay buffers for Design For Testability and, more particularly, to integrated circuits, methods, systems, and apparatuses that gate the buffers in functional mode across all the scan-shift paths in a circuit design.

### BACKGROUND

Applicant has identified many technical challenges and difficulties associated with the use of scan-test shift delay buffers for DFT (Design For Testability). Through applied effort, ingenuity, and innovation, Applicant has solved problems related to the use of such scan-test shift delay buffers by developing solutions embodied in the present disclosure, which are described in detail below.

### BRIEF SUMMARY

Various embodiments described herein related to integrated circuits, methods, apparatuses, and systems for gating scan-test shift delay buffers for DFT (Design For Testability) in functional mode across all the scan-shift paths in the design.

In accordance with various embodiments of the present disclosure, an integrated circuit is provided. In some embodiments, the integrated circuit comprises a functional data path and a scan-data path. At least a portion of the scan-data path is separate from the functional data path. The portion of the scan-data path which is separate from the functional data path comprises a combined gating/delay element for preventing a scan-data signal from reaching any elements downstream of the combined gating/delay element during a scan mode and for providing some or all of a desired signal delay in the portion of the scan-data path which is separate from the functional data path.

In some embodiments, the combined gating/delay element comprises an AND gate, a NAND gate, or a NOR gate.

In some embodiments, the combined gating/delay element comprises a NAND gate comprising a first and second transistors in series, the second transistor being closer to a ground connection than is the first transistor. A scan-enable source of the integrated circuit is connected to an input of the NAND gate leading to the first transistor.

In some embodiments, the combined gating/delay element comprises a NOR gate comprising a first and second transistors in series, the first transistor being closer to a source voltage connection than is the second transistor. A scan-enable source of the integrated circuit is connected to an input of the NOR gate leading to the second transistor.

In some embodiments, the scan-data path further comprises one or more delay elements downstream of the combined gating/delay element. The combined gating/delay element and the one or more delay elements downstream of the combined gating/delay element together provide all of the desired signal delay in the portion of the scan-data path which is separate from the functional data path.

In some embodiments, the one or more delay elements downstream of the combined gating/delay element comprise one or more buffers and/or one or more inverters.

In accordance with various embodiments of the present disclosure, a method is provided. In some embodiments, the method comprises inserting a combined gating/delay element into a portion of a scan-data path of an integrated circuit that is separate from a functional data path of the integrated circuit. The combined gating/delay element prevents a scan-data signal from reaching any elements downstream of the combined gating/delay element during a scan mode and provides some or all of a desired signal delay in the portion of the scan-data path which is separate from the functional data path.

In accordance with various embodiments of the present disclosure, a computer-implemented method is provided. The computer-implemented method comprises parsing a list of electronic components and electrical connections of an electronic circuit; identifying one or more scan flip-flops (SFFs), buffers, and/or inverters in the list of electronic components; for each SFF identified in the list of electronic components and electrical connections, tracing a corresponding series of buffers and/or inverters back from a scan input of each corresponding SFF until (a) a flip-flop output or (b) a buffer or inverter with a fanout greater than one is encountered; and revising the list of electronic components and electrical connections by (a) replacing a foremost buffer or inverter in each series of buffers and/or inverters with a scan-enable (SE)-connected combined gating/delay component, or (b) adding an SE-connected combined gating/delay component immediately preceding the foremost buffer or inverter in each series of buffers and/or inverters.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1A provides an example Design For Testability (DFT) circuit design having scan-shift paths for testing;

FIG. 1B illustrates an example Scan Flip-Flop (SFF) of the circuit design of FIG. 1B;

FIG. 2 illustrates a portion of an example DFT circuit design having scan-test shift delay buffers;

FIG. 3 illustrates an example DFT circuit design having scan-test shift delay buffers;

FIG. 4 illustrates an example DFT circuit design having gated scan-test shift delay buffers, in accordance with some embodiments of the present disclosure;

FIG. 5 illustrates a block diagram of an example apparatus for gating scan-test shift delay buffers in a DFT circuit design, in accordance with some embodiments of the present disclosure;

FIGS. 6 and 7 illustrate example combined gating/delay components, in accordance with some embodiments of the present disclosure; and

FIG. 8 provides an example flow diagram illustrating an example method for gating scan-test shift delay buffers in a DFT circuit design, in accordance with some embodiments of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

A significant major part of power consumption in contemporary Application Specific Integrated Circuits (ASICs) is attributed to high-speed, high-compute digital designs, with the problem becoming more severe at increased temperatures. Power consumption is particularly critical in battery operated chips. Modern complex Integrated Circuits (ICs)) commonly comprise over a million gates, with higher frequency operation further stressing the power integrity and viable operation of the IC.

Power often becomes a major bottleneck while implementing a high-speed digital design. There are design trade-offs between low power, operating frequency, and circuit size. Optimization in all three areas is desired, but typically not possible. Dynamic power consumption in digital designs occurs primarily during logic gate switching.

Modern complex ICs commonly use scan-path testing, which involves scan-shift data paths. Scan-path testing involves switching all the storage elements of the circuit from their functional mode (which may also be termed an operational mode) to a test mode shift register configuration. A scan-in I/O and a scan-out I/O allow data to be read into and read out from this reconfiguration for test purposes. Such scan-path testing employs scan-test shift delay buffers that remain connected to the functional logic and consume parasitic dynamic power for the lifetime of the IC. The buffers inserted in the scan-path, primarily for hold time correction in the scan-shift path, will switch in both functional as well as scan-shift modes. These buffers serve no meaningful purpose while switching in the functional mode, thereby resulting in unnecessary dynamic power dissipation in the functional mode.

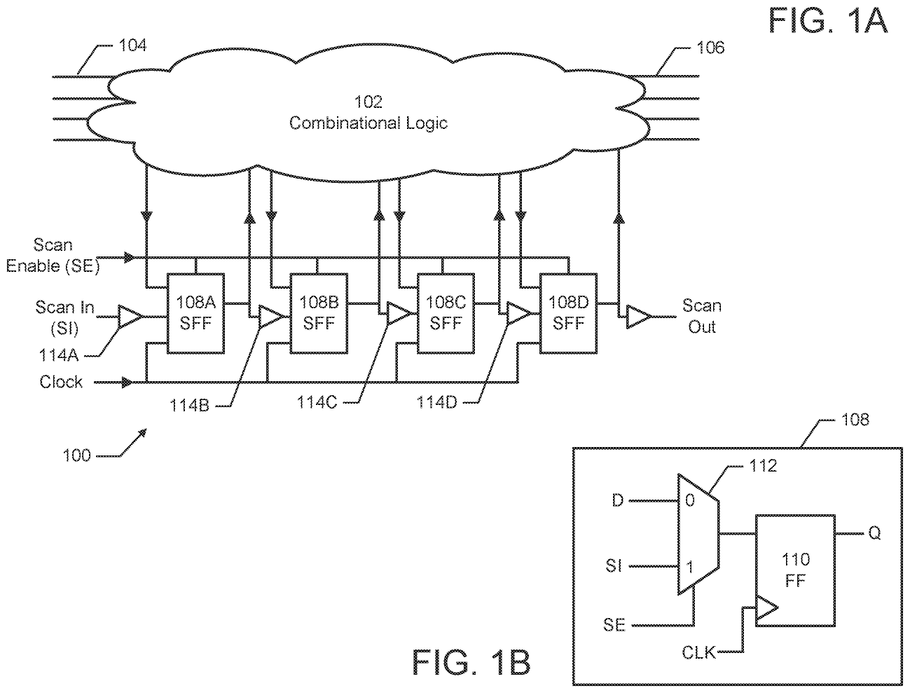

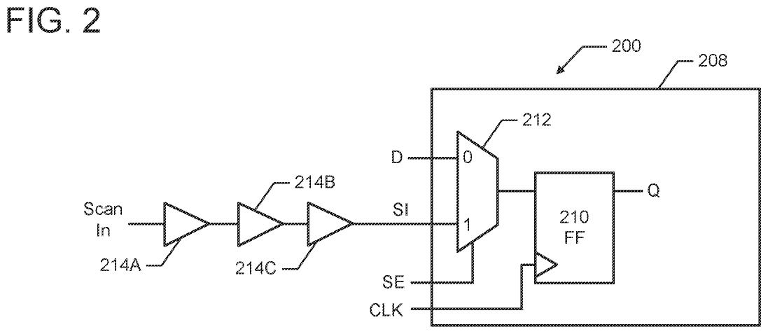

FIG. 1A illustrates an example Design For Testability circuit design having scan-shift paths for testing. The circuit design 100 of FIG. 1A illustrates functional combinational logic 102 with a plurality of inputs 104 and a plurality of outputs 106 traversing the functional combinational cloud. The scan-shift paths comprise a plurality of Scan Flip-Flops (SFFs) 108 (e.g., 108A, 108B, 108C, 108D). As illustrated in FIG. 1A, each SFF receives a signal from the combinational logic 102 (labeled D in FIG. 1B), a Scan Enable (SE) signal, a Scan In (SI) signal (which may come from another SFF, such as via corresponding buffers 114A, 114B, 114C, 114D which provide hold time correction), and a clock signal. As illustrated in FIG. 1B, in some embodiments each SFF 108 comprises a multiplexer 112 and a Flip-Flop (FF) 110.

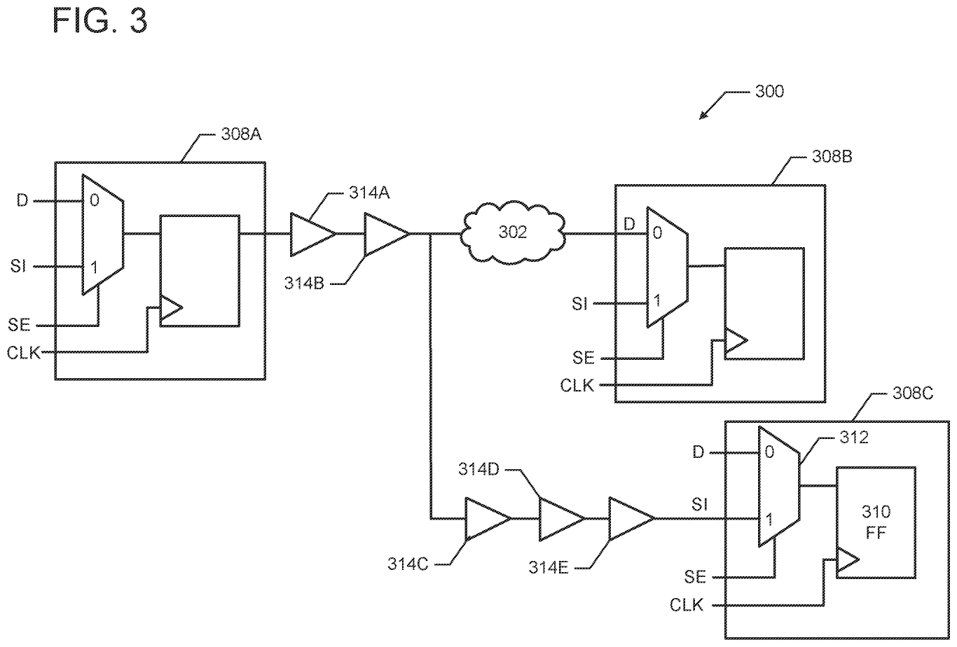

As described above, buffers are commonly inserted in the scan-path for hold time correction. (In addition to buffers, inverters may alternatively or additionally be inserted in the scan-path. For simplicity, this disclosure will refer primarily to buffers, although embodiments of the disclosure also apply to inverters in the scan-path.) FIG. 2 illustrates a portion of an example circuit design having scan-test shift delay buffers. In the circuit design portion 200 of FIG. 2, an SFF 208 comprises a multiplexer 212 and a Flip-Flop 210. Three buffers 214A, 214B, 214C are connected in series to the SE input of the SFF 208 for hold time correction. The scan-shift buffers would switch in cases when the buffer inputs branch out from an external functional data path (which may also be termed an operational data path). When the circuit of FIG. 2 is in functional mode, Scan Enable (SE) is set to ‘0’ and Scan In (SI) remains disconnected from the FF 210.

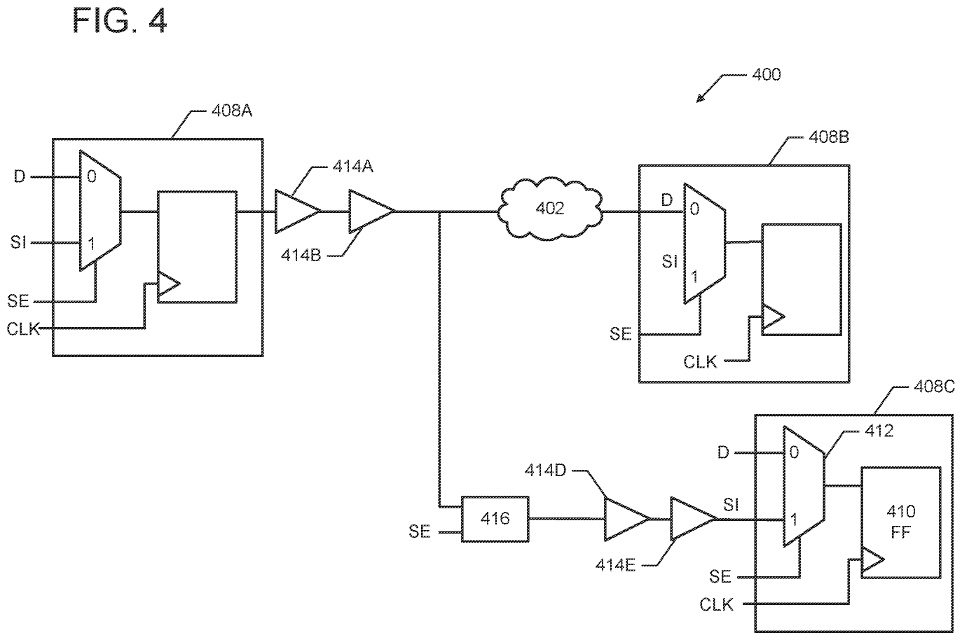

FIG. 3 illustrates an example DFT circuit design showing internal register to register data paths. The circuit design 300 of FIG. 3 includes functional logic 302 and three SFFs 308A, 308B, 308C. In FIG. 3, two scan-shift buffers 314A, 314B are shared with the functional data path, and three scan-shift buffers 314C, 314D, 314E are dedicated to the scan-shift path. When the circuit of FIG. 3 is in functional mode, Scan Enable (SE) is set to ‘0’ and Scan In (SI) to SFF 308C remains disconnected from the Flip-Flop 310. Although the output of the scan-shift buffers 314A, 314B, 314C, 314D, and 314E is blocked at the scan multiplexer 312, the scan-shift buffers 314C, 314D, and 314E continue to switch when in functional mode, thereby consuming parasitic power. In contrast, scan-shift buffers 314A, 314B are shared with the functional data path and are therefore not considered parasitic.

Various embodiments of the present disclosure overcome the above technical challenges and difficulties and provide various technical improvements and advantages based on, for example, but not limited to, providing example integrated circuits, methods, devices, and systems for gating scan-test shift delay buffers for DFT in functional mode across some or all the scan-shift paths in the design.

Embodiments of the present disclosure provide a low-cost power saving mechanism to mitigate the power-dissipation in functional mode due to the buffers laid out in the scan-shift data path. This mechanism is applicable to digital designs that employ scan-test shift delay buffers for DFT that remain connected to the functional logic and consume parasitic dynamic power for the lifetime of a chip. In various embodiments, this methodology effectively gates the buffers in functional mode across all the scan-shift paths in the design, with little to no impact on design functionality or timing. For high-speed, multiple clock domain designs, the dynamic power saving provided can be significant. Further, the design cycle time overhead for its deployment can be negligible and the area requirement for the proposed implementation can be insignificant.

Embodiments of the present disclosure mitigate the parasitic power drain described above by isolating the scan-shift buffers from the switching functional nodes. In various embodiments, a combined gating/delay component or circuitry is inserted at the beginning of the parasitic section of the scan-shift buffer chain. That is, the combined gating/delay component both gates the scan-shift buffers from the functional nodes (i.e., does not allow the data signal to flow to the scan-shift buffers that are not required for the functional logic when scan enable=0) and also provides some delay such that one or more of the scan-shift buffers can be eliminated while maintaining the desired hold time. The number of scan-shift buffers that can be eliminated (i.e., replaced with a combined gating/delay component) varies depending on the hold time margins of the scan-shift path and the amount of delay provided by the combined gating/delay component. The amount of delay provided by the combined gating/delay component varies based on the type of component and the specific circuits/components used in the combined gating/delay component. In some embodiments, the combined gating/delay component comprises a two-input AND gate, NAND gate, or NOR gate. While the combined gating/delay component may comprise an AND gate, a NAND gate, or a NOR gate, any other suitable component/circuitry that provides both gating and delay may be used.

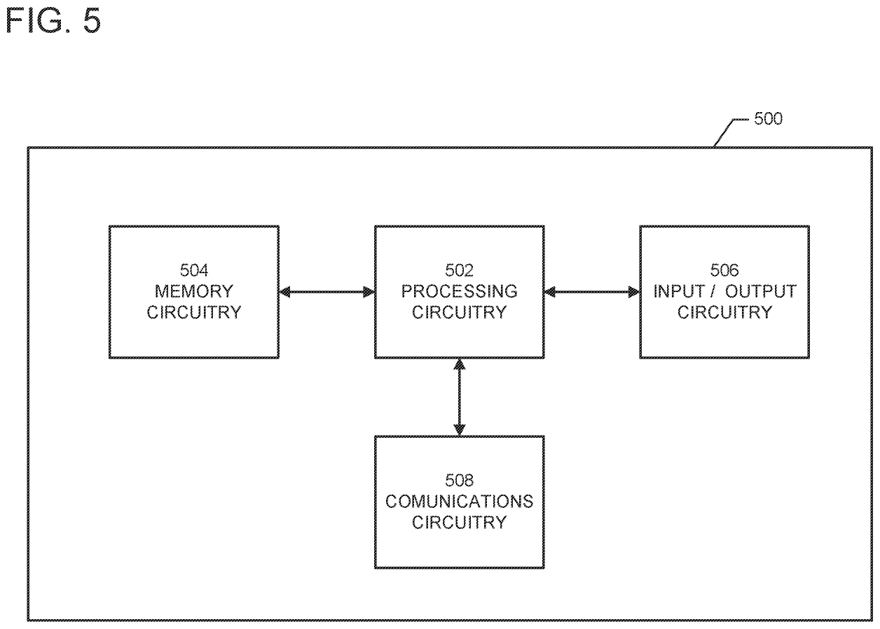

FIG. 4 illustrates an example DFT circuit design showing internal register to register data paths, similar to the circuit of FIG. 3. The circuit design 400 of FIG. 4 includes functional logic 402 and three SFFs 408A, 408B, 408C. In FIG. 4, two scan-shift buffers 414A, 414B are shared with the functional data path, and two scan-shift buffers 414D, 414E are dedicated to the scan-shift path. When the circuit of FIG. 4 is in functional mode, Scan Enable (SE) is set to ‘0’ and Scan In (SI) to SFF 408C is blocked at the scan multiplexer 412 and therefore disconnected from the Flip-Flop 410.

The circuit design 400 of FIG. 4 further includes a combined gating/delay component 416 (for example, but not limited to, an AND gate, NAND gate, or NOR gate) at the beginning of the parasitic section of the scan-shift buffer chain, i.e., before the scan-shift buffers 414D, 414E. Note that there are only two scan-shift buffers 414D, 414E dedicated to the scan-shift path, as one of the scan-shift buffers from FIG. 3 (314C) was replaced by the combined gating/delay component 416. The combined gating/delay component 416 provides both gating of the scan-shift buffer chain and some of the delay needed for hold time correction.

The first input of the combined gating/delay component 416 is the data line between scan-shift buffer 414B and scan-shift buffer 414D, while the second input of the combined gating/delay component 416 is connected to the Scan Enable signal so as to deactivate the scan-shift path only in the functional mode, i.e., when SE=0. As such, when SE=0 in the functional mode, no signal is passed to the parasitic section of the scan-shift buffer chain (scan-shift buffers 414D, 414E) and therefore there is no switching in the scan-shift buffers 414D, 414E when in the functional mode. Parasitic power loss due to unnecessary switching of the scan-shift buffers 414D, 414E is thereby prevented. Note that only scan-shift buffers that branch out from the main logic path (i.e., that are not part of the main logic path) are gated by the combined gating/delay component (i.e., the combined gating/delay component 416).

In various embodiments, the routing complexity of the SE signal when adding such combined gating/delay components is minimal as there is typically an abundance of SE nodes in such circuit designs. In various embodiments, the SE signal can typically be tapped from the nearest Scan Flip-Flop. In various embodiments, to case things further SE is unconstrained by timing and is usually declared as a false timing path.

In various embodiments of the present disclosure, a combined gating/delay component (such as a two input AND gate, NAND gate, or NOR gate) may be inserted at the beginning of the parasitic section of a plurality of different scan-shift buffer chains in an IC. In various embodiments of the present disclosure, scan-shift buffer chains may comprise both parasitic and non-parasitic (i.e., functional) sections (in which case the combined gating/delay component is inserted at the beginning of the parasitic section) or may comprise parasitic sections only (in which case the combined gating/delay component is inserted at the beginning of the scan-shift buffer chain).

In some embodiments, the methodology of embodiments of the invention may insert a combined gating/delay component at the beginning of a parasitic section of a scan-shift buffer chain of any length (i.e., any number of scan-shift buffers). In some embodiments, a combined gating/delay component may be inserted before a single parasitic scan-shift buffer. In some embodiments, a combined gating/delay component may replace a single parasitic scan-shift buffer.

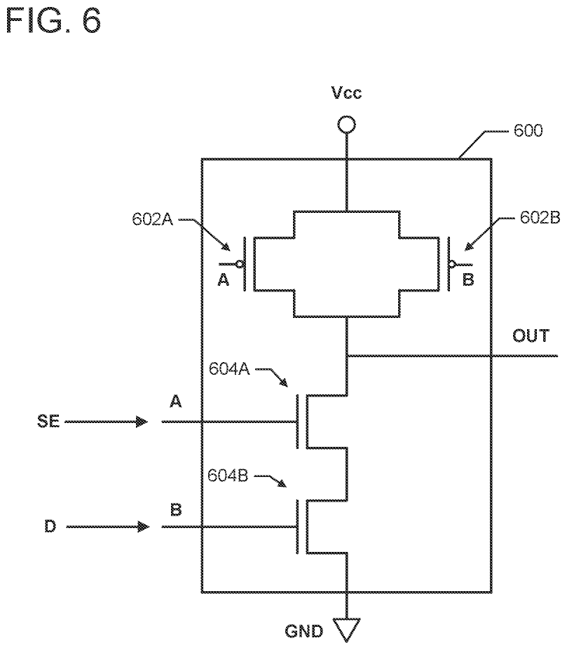

FIG. 5 illustrates an exemplary block diagram of an example apparatus that may be specially configured in accordance with an example embodiment of the present disclosure. Specifically, FIG. 5 depicts an example computing apparatus 500 (“apparatus 500”) specially configured in accordance with at least some example embodiments of the present disclosure.

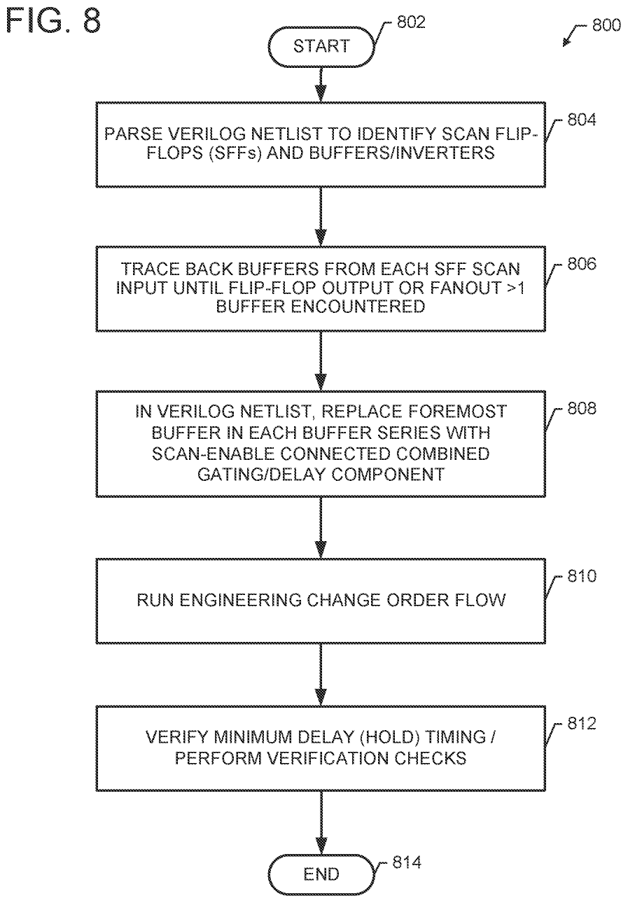

The apparatus 500 includes processor or processing circuitry 502, memory circuitry 504, input/output circuitry 506, and communications circuitry 508. In some embodiments, the apparatus 500 is configured to execute and perform the operations described herein. For example, the apparatus 500 may be configured to implement a method for gating parasitic buffers as described below in relation to FIG. 8.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory(ies), circuitry(ies), and/or the like to perform their associated functions such that duplicate hardware is not required for each set of circuitry.

In various embodiments, such a computing apparatus 500 may refer to, for example, one or more computers, computing entities, desktop computers, mobile phones, tablets, phablets, notebooks, laptops, distributed systems, servers, or the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein. In one embodiment, these functions, operations, and/or processes can be performed on data, content, information, and/or similar terms used herein. In this regard, the apparatus 500 embodies a particular, specially configured computing entity transformed to enable the specific operations described herein and provide the specific advantages associated therewith, as described herein.

Processing circuity 502 may be embodied in a number of different ways. In various embodiments, the use of the terms “processor” or “processing circuity” should be understood to include a single core processor, a multi-core processor, multiple processors internal to the apparatus 500, and/or one or more remote or “cloud” processor(s) external to the apparatus 500. In some example embodiments, processing circuitry 502 may include one or more processing devices configured to perform independently. Alternatively, or additionally, processing circuitry 502 may include one or more processor(s) configured in tandem via a bus to enable independent execution of operations, instructions, pipelining, and/or multithreading.

In an example embodiment, the processing circuitry 502 may be configured to execute instructions stored in the memory circuitry 504 or otherwise accessible to the processor. Alternatively, or additionally, the processing circuitry 502 may be configured to execute hard-coded functionality. As such, whether configured by hardware or software methods, or by a combination thereof, processing circuitry 502 may represent an entity (e.g., physically embodied in circuitry) capable of performing operations according to embodiments of the present disclosure while configured accordingly. Alternatively, or additionally, processing circuitry 502 may be embodied as an executor of software instructions, and the instructions may specifically configure the processing circuitry 502 to perform the various algorithms embodied in one or more operations described herein when such instructions are executed. In some embodiments, the processing circuitry 502 includes hardware, software, firmware, and/or a combination thereof that performs one or more operations described herein.

In some embodiments, the processing circuitry 502 (and/or co-processor or any other processing circuitry assisting or otherwise associated with the processor) is/are in communication with the memory circuitry 504 via a bus for passing information among components of the apparatus 500.

Memory or memory circuitry 204 may be non-transitory and may include, for example, one or more volatile and/or non-volatile memories. In some embodiments, the memory circuitry 504 includes or embodies an electronic storage device (e.g., a computer readable storage medium). In some embodiments, the memory circuitry 504 is configured to store information, data, content, applications, instructions, or the like, for enabling an apparatus 500 to carry out various operations and/or functions in accordance with example embodiments of the present disclosure.

Input/output circuitry 506 may be included in the apparatus 500. In some embodiments, input/output circuitry 506 may provide output to the user and/or receive input from a user. The input/output circuitry 506 may be in communication with the processing circuitry 502 to provide such functionality. The input/output circuitry 506 may comprise one or more user interface(s). In some embodiments, a user interface may include a display that comprises the interface(s) rendered as a web user interface, an application user interface, a user device, a backend system, or the like. In some embodiments, the input/output circuitry 506 also includes a keyboard, a mouse, a joystick, a touch screen, touch areas, soft keys a microphone, a speaker, or other input/output mechanisms. The processing circuitry 502 and/or input/output circuitry 506 may be configured to control one or more operations and/or functions of one or more user interface elements through computer program instructions (e.g., software and/or firmware) stored on a memory accessible to the processor (e.g., memory circuitry 504, and/or the like). In some embodiments, the input/output circuitry 506 includes or utilizes a user-facing application to provide input/output functionality to a computing device and/or other display associated with a user.

Communications circuitry 508 may be included in the apparatus 500. The communications circuitry 508 may include any means such as a device or circuitry embodied in either hardware or a combination of hardware and software that is configured to receive and/or transmit data from/to a network and/or any other device, circuitry, or module in communication with the apparatus 500. In some embodiments the communications circuitry 508 includes, for example, a network interface for enabling communications with a wired or wireless communications network. Additionally or alternatively, the communications circuitry 508 may include one or more network interface card(s), antenna(s), bus(es), switch(es), router(s), modem(s), and supporting hardware, firmware, and/or software, or any other device suitable for enabling communications via one or more communications network(s). In some embodiments, the communications circuitry 508 may include circuitry for interacting with an antenna(s) and/or other hardware or software to cause transmission of signals via the antenna(s) and/or to handle receipt of signals received via the antenna(s). In some embodiments, the communications circuitry 508 enables transmission to and/or receipt of data from a user device, one or more sensors, and/or other external computing device(s) in communication with the apparatus 500.

In some embodiments, two or more of the sets of circuitries 502-508 are combinable. Alternatively, or additionally, one or more of the sets of circuitry 502-508 perform some or all of the operations and/or functionality described herein as being associated with another circuitry. In some embodiments, two or more of the sets of circuitry 502-508 are combined into a single module embodied in hardware, software, firmware, and/or a combination thereof.

As described above, the combined gating/delay component of embodiments of the present disclosure may comprise, for example, an AND gate, a NAND gate, or a NOR gate.

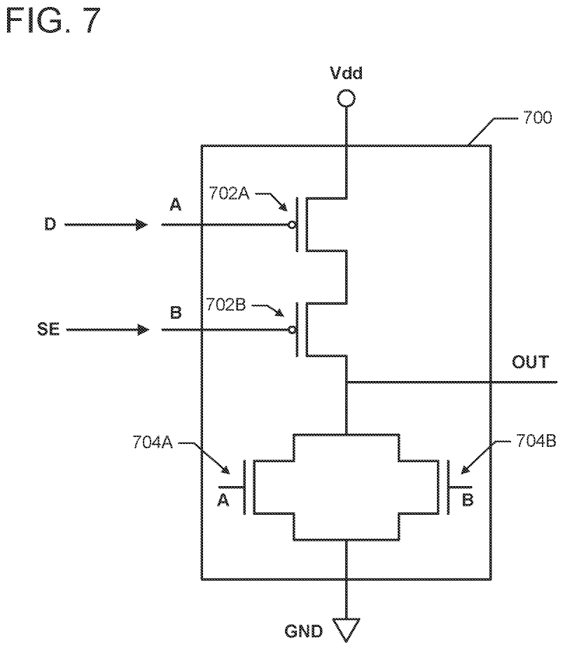

FIG. 6 illustrates an example combined gating/delay component comprising a NAND gate. As seen in FIG. 6, the example NAND gate 600 comprises first and second parallel p-channel MOSFET transistors 602A, 602B connected to a supply voltage Vdd at one end and connected at the opposite end to first and second n-channel MOSFET transistors 604A, 604B in series, which are in turn connected to ground. The A input of the NAND gate 600 is connected to the gate of the first n-channel MOSFET transistor 604A and the B input of the NAND gate 600 is connected to the gate of the second n-channel MOSFET transistor 604B. The output of the NAND gate 600 is connected to a node between the two parallel p-channel MOSFET transistors 602A, 602B and the two n-channel MOSFET transistors 604A, 604B in series.

To ensure that the NAND gate 600 provides the desired delay (as described above), the SE signal is connected to the A input (i.e., the input further from the supply (ground)) and the data signal (“D) is connected to the B input (i.e., the input closer to the supply (ground)). When in scan mode, the SE signal is steady and the data signal is varying. Since the SE signal is steady, whichever n-channel MOSFET the SE signal is connected to will be precharged. However, it is desirable in some embodiments that the second n-channel MOSFET transistor 604B not be precharged by the SE signal. If the second n-channel MOSFET transistor 604B is precharged by the SE signal, then the NAND gate would operate faster and would not provide the desired amount of delay. By connecting the SE signal to the A input (i.e., the input further from the supply (ground)) and not precharging the second n-channel MOSFET transistor 604B, the desired amount of delay is provided.

FIG. 7 illustrates an example combined gating/delay component comprising a NOR gate. As seen in FIG. 7, the example NOR gate 700 comprises first and second p-channel MOSFET transistors 702A, 704B in series connected to a supply voltage Vdd at one end and connected at the opposite end to first and second parallel n-channel MOSFET transistors 704A, 704B, which are in turn connected to ground. The A input of the NOR gate 700 is connected to the gate of the first p-channel MOSFET transistor 702A and the B input of the NOR gate 700 is connected to the gate of the second p-channel MOSFET transistor 702B. The output of the NOR gate 700 is connected to a node between the two p-channel MOSFET transistors 702A, 702B in series and the two parallel n-channel MOSFET transistors 704A, 704B.

To ensure that the NOR gate 700 provides the desired delay (as described above), the SE signal is connected to the B input (i.e., the input further from the supply (Vdd)) and the data signal (“D) is connected to the A input (i.e., the input closer to the supply (Vdd)). When in scan mode, the SE signal is steady and the data signal is varying. Since the SE signal is steady, whichever p-channel MOSFET the SE signal is connected to will be precharged. However, it is desirable in some embodiments that the first p-channel MOSFET transistor 702A not be precharged by the SE signal. If the first p-channel MOSFET transistor 702A is precharged by the SE signal, then the NOR gate would operate faster and would not provide the desired amount of delay. By connecting the SE signal to the B input (i.e., the input further from the supply (Vdd)) and not precharging the first p-channel MOSFET transistor 702A, the desired amount of delay is provided.

Reference will now be made to FIG. 8, which provides a flowchart illustrating example steps, processes, procedures, and/or operations in accordance with various embodiments of the present disclosure. Various methods described herein, including, for example, example methods as shown in FIG. 8, may provide various technical benefits and improvements. It is noted that each block of the flowchart, and combinations of blocks in the flowchart, may be implemented by various means such as hardware, firmware, circuitry and/or other devices associated with execution of software including one or more computer program instructions. For example, one or more of the procedures described in FIG. 8 may be embodied by computer program instructions, which may be stored by a non-transitory memory of an apparatus employing an embodiment of the present disclosure and executed by a processor in the apparatus. These computer program instructions may direct a computer or other programmable apparatus to function in a particular manner, such that the instructions stored in the computer-readable storage memory produce an article of manufacture, the execution of which implements the function specified in the flowchart block(s).

As described above and as will be appreciated based on this disclosure, embodiments of the present disclosure may be configured as methods, mobile devices, backend network devices, and the like. Accordingly, embodiments may comprise various means including entirely of hardware or any combination of software and hardware. Furthermore, embodiments may take the form of a computer program product on at least one non-transitory computer-readable storage medium having computer-readable program instructions (e.g., computer software) embodied in the storage medium. Similarly, embodiments may take the form of a computer program code stored on at least one non-transitory computer-readable storage medium. Any suitable computer-readable storage medium may be utilized including non-transitory hard disks, CD-ROMs, flash memory, optical storage devices, or magnetic storage devices.

Referring now to FIG. 8, an example flow diagram illustrating an example method 800 for gating parasitic buffers in accordance with some embodiments of the present disclosure is illustrated. In some embodiments, the example method 800 may be implemented by an example computing apparatus described herein, including, but not limited to, the example apparatus 500 described above in connection with FIG. 5. The example method 800 provides an automatable flow for determining circuit modifications that may be implemented to gate the parasitic buffers and reduce power consumption.

In the example method shown in FIG. 8, the example method 800 starts at step/operation 802. At step/operation 804, a processor (such as, but not limited to, the processing circuitry 502 of the apparatus 500 described above in connection with FIG. 5) parses a post implementation netlist (typically a Verilog netlist) from a developed IC to identify all of the Scan Flip-Flop and buffer/inverter elements along with their fanout number, and then creates/stores (“dumps”) a file with this information. Verilog is a hardware description language used in the design and verification of digital circuits. A netlist is a representation of a digital circuit in terms of gates and interconnections between them. In some embodiments, this pre-processing step will only retain parts of the netlist needed to extract the parasitic scan-shift buffers.

At step/operation 806, a processor (such as, but not limited to, the processing circuitry 502 of the apparatus 500 described above in connection with FIG. 5) traces back, using the file dumped at step/operation 804, the series of buffers from each Scan Input of each SFF and follows the buffer chain trace until a Flip-Flop output (Q/Qbar) or a buffer with a fanout>1 (i.e., a buffer whose output is connected to more than one input) is encountered. In some embodiments, all of these identified leading buffers are stored in another file.

At step/operation 808, a processor (such as, but not limited to, the processing circuitry 502 of the apparatus 500 described above in connection with FIG. 5) replaces, in the original Verilog netlist, the foremost buffer in each of the buffer series with an SE-connected combined gating/delay component. The Verilog netlist with these replacements made is now an engineering change order (ECO)-ready netlist.

At step/operation 810, a processor (such as, but not limited to, the processing circuitry 502 of the apparatus 500 described above in connection with FIG. 5) runs an ECO flow to insert the combined gating/delay components and perform the SE routing.

At step/operation 812, a processor (such as, but not limited to, the processing circuitry 502 of the apparatus 500 described above in connection with FIG. 5) posts the ECO run, verifies the minimum delay (hold) timing, performs formal verification checks in the functional mode to check functional sanity, and, if needed, runs a post-layout functional simulation.

In the example shown in FIG. 8, the example method 800 ends at step/operation 814.

In some embodiments, the example method shown in FIG. 8 takes a fraction of the design cycle time and can be effortlessly accommodated post the timing sign-off step of the post-layout netlist.

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to fragmented wideband tympanometry techniques for true wireless stereo, however, one skilled in the art may recognize that such principles may be applied to any audio device. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of integrated circuit which uses scan-test shift delay buffers for DFT, such as but not limited to microcontrollers (MCUs), microprocessors (CPUs), wired and wireless communication systems-on-a-chip (SoCs), automotive SoCs, networking SoCs, image processing SoCs, and artificial intelligence chips.

Within the appended claims, unless the specific term “means for” or “step for” is used within a given claim, it is not intended that the claim be interpreted under 35 U.S.C. 112, paragraph 6.

What is claimed is:

1. An integrated circuit comprising:
a functional data path; and
a scan-data path, at least a portion of which is separate from the functional data path;
wherein the portion of the scan-data path which is separate from the functional data path comprises a combined gating/delay element for preventing a scan-data signal from reaching any elements downstream of the combined gating/delay element during a scan mode and for providing some or all of a desired signal delay in the portion of the scan-data path which is separate from the functional data path.

2. The integrated circuit of claim 1, wherein the combined gating/delay element comprises an AND gate, a NAND gate, or a NOR gate.

3. The integrated circuit of claim 2, wherein the combined gating/delay element comprises a NAND gate comprising a first and second transistors in series, the second transistor being closer to a ground connection than is the first transistor; and
wherein a scan-enable source of the integrated circuit is connected to an input of the NAND gate leading to the first transistor.

4. The integrated circuit of claim 2, wherein the combined gating/delay element comprises a NOR gate comprising a first and second transistors in series, the first transistor being closer to a source voltage connection than is the second transistor; and
wherein a scan-enable source of the integrated circuit is connected to an input of the NOR gate leading to the second transistor.

5. The integrated circuit of claim 1, wherein the scan-data path further comprises one or more delay elements downstream of the combined gating/delay element; and
wherein the combined gating/delay element and the one or more delay elements downstream of the combined gating/delay element together provide all of the desired signal delay in the portion of the scan-data path which is separate from the functional data path.

6. The integrated circuit of claim 5, wherein the one or more delay elements downstream of the combined gating/delay element comprise one or more buffers and/or one or more inverters.

7. A method comprising:
inserting a combined gating/delay element into a portion of a scan-data path of an integrated circuit that is separate from a functional data path of the integrated circuit;
wherein the combined gating/delay element prevents a scan-data signal from reaching any elements downstream of the combined gating/delay element during a scan mode and provides some or all of a desired signal delay in the portion of the scan-data path which is separate from the functional data path.

8. The method of claim 7, wherein the combined gating/delay element comprises an AND gate, a NAND gate, or a NOR gate.

9. The method of claim 8, wherein the combined gating/delay element comprises a NAND gate comprising a first and second transistors in series, the second transistor being closer to a ground connection than is the first transistor; and
wherein the method further comprises connecting a scan-enable source of the integrated circuit is connected to an input of the NAND gate leading to the first transistor.

10. The method of claim 8, wherein the combined gating/delay element comprises a NOR gate comprising a first and second transistors in series, the first transistor being closer to a source voltage connection than is the second transistor; and
wherein the method further comprises connecting a scan-enable source of the integrated circuit to an input of the NOR gate leading to the second transistor.

11. The method of claim 7, wherein the scan-data path further comprises one or more delay elements downstream of the combined gating/delay element; and
wherein the combined gating/delay element and the one or more delay elements downstream of the combined gating/delay element together provide all of the desired signal delay in the portion of the scan-data path which is separate from the functional data path.

12. The method of claim 11, wherein the one or more delay elements downstream of the combined gating/delay element comprise one or more buffers and/or one or more inverters.

13. A computer-implemented method comprising:
parsing a list of electronic components and electrical connections of an electronic circuit;
identifying one or more scan flip-flops (SFFs), buffers, and/or inverters in the list of electronic components;
for each SFF identified in the list of electronic components and electrical connections, tracing a corresponding series of buffers and/or inverters back from a scan input of each corresponding SFF until (a) a flip-flop output or (b) a buffer or inverter with a fanout greater than one is encountered; and
revising the list of electronic components and electrical connections by (a) replacing a foremost buffer or inverter in each series of buffers and/or inverters with a scan-enable (SE)-connected combined gating/delay component, or (b) adding an SE-connected combined gating/delay component immediately preceding the foremost buffer or inverter in each series of buffers and/or inverters.

14. The method of claim 13, wherein the combined gating/delay element comprises an AND gate, a NAND gate, or a NOR gate.

15. The method of claim 13, wherein the list of electronic components and electrical connections comprises a netlist.

16. The method of claim 15, wherein the netlist comprises a Verilog netlist.

17. The method of claim 13, further comprising:
running an engineering change order (ECO) flow on the revised list of electronic components and electrical connections.

18. The method of claim 17, further comprising:
verifying minimum delay or hold timing of the revised list of electronic components and electrical connections.

19. The method of claim 17, further comprising:
performing one or more verification checks in a functional mode using the revised list of electronic components and electrical connections.

20. The method of claim 17, further comprising:
performing one or more functional simulations using the revised list of electronic components and electrical connections.
